(19) United States
(12) Patent Application Publication
(10) Pub. No.: US 2014/0116771 A1
(43) Pub. Date: May 1, 2014

(54) ELECTRONIC DEVICE CASING

(71) Applicant: DENSO CORPORATION, Kariya-city (JP)

(72) Inventors: Kazutaka Masuda, Kariya-city (JP); Toshihide Kondo, Chita-gun (JP)

(73) Assignee: DENSO CORPORATION, Kariya-city (JP)

(21) Appl. No.: 14/052,854

(22) Filed: Oct. 14, 2013

(30) Foreign Application Priority Data
Nov. 1, 2012 (JP) 2012-242239

(51) Int. Cl. H05K 5/00

(52) U.S. Cl. CPC H05K 5/00
USPC 174/520

(57) ABSTRACT

An electronic device casing includes a peripheral wall portion enclosing an outer circumference of a substrate provided with a connector, an opening portion formed in the peripheral wall portion to have an opening from which the connector is exposed to an exterior, an upper plate portion covering an upper part of the peripheral wall portion, and a protrusion portion protruding from an end part of the upper plate portion and covering an upper part of the connector exposed from the opening portion. The protrusion portion has a first end part connected to the upper plate portion, and a second end part opposite from the first end part in a protruding direction of the protrusion portion. The second end part is higher than the first end part.

### CROSS REFERENCE TO RELATED APPLICATION

This application is based on and incorporates herein by reference Japanese Patent Application No. 2012-242239 filed on Nov. 1, 2012.

### TECHNICAL FIELD

The present disclosure relates to an electronic device casing which accommodates a substrate provided with a connector.

### BACKGROUND

Conventionally, a casing is disclosed in Patent Document 1 (JP 2000-517474 A corresponding to U.S. Pat. No. 6,364,144 B1), for example, as an electronic device casing which accommodates a substrate provided with a connector.

The casing is a member accommodating a substrate provided with electronic parts for an electronic circuit and a connector. The casing includes a peripheral wall portion, an opening portion, an upper plate portion and an eaves portion.

The peripheral wall portion encloses an outer circumference of the substrate provided with the connector. The opening portion is formed on the peripheral wall, and the connector is exposed to an exterior of the casing from the opening portion. The upper plate portion covers an upper part of the peripheral wall portion. The eaves portion protrudes from a front end part of the upper plate portion horizontally frontward and covers an upper part of the connector exposed from the opening portion, thereby limiting exposure of the connector to water.

When a connector (second connector) is inserted into the connector (first connector) provided on the substrate, the second connector is sandwiched between fingers from above and from underneath. Also when the second connector is pulled out of the first connector, the second connector is sandwiched between fingers from above and from underneath.

The eaves portion of the casing protrudes horizontally forward. Thus, a space between the eaves portion and the first connector mounted on the substrate may be quite narrow, and a finger of a worker may thus contact the eaves portion. Therefore, connection or disconnection between the connectors may be difficult.

### SUMMARY

It is an objective of the present disclosure to provide an electronic device casing capable of improving workability of connection and disconnection of a connector while resistance of the connector to water is ensured.

According to an aspect of the present disclosure, an electronic device casing includes a peripheral wall portion, an opening portion, an upper plate portion and a protrusion portion. The peripheral wall portion encloses an outer circumference of a substrate provided with a connector, and the opening portion is formed in the peripheral wall portion to have an opening from which the connector is exposed to an exterior. The upper plate portion covers an upper part of the peripheral wall portion. The protrusion portion protrudes from an end part of the upper plate portion and covers an upper part of the connector exposed from the opening portion. The protrusion portion has a first end part connected to the upper plate portion, and a second end part opposite from the first end part in a protruding direction of the protrusion portion. The second end part is higher than the first end part.

Accordingly, a space between the connector and the protrusion portion can be made to be larger than a case in which a protrusion portion protrudes horizontally from an end portion of the upper plate portion. In other words, the space between the connector and the protrusion portion can be made to be larger than a case in which the height of first end part and the height of the second end part are the same. Hence, contact between a finger of a worker and the protrusion portion can be restricted during connecting or disconnecting the connector. Therefore, resistance to water can be ensured by the protrusion portion while workability of connection or disconnection of the connector can be improved.

### BRIEF DESCRIPTION OF THE DRAWINGS

The disclosure, together with additional objectives, features and advantages thereof, will be best understood from the following description, the appended claims and the accompanying drawings, in which:

FIG. 1 is a perspective view showing an air-bag control device according to an exemplar embodiment of the present disclosure;

FIG. 2 is a top view showing a substrate of the air-bag control device according to the exemplar embodiment;

FIG. 3 is a top view showing a casing of the air-bag control device according to the exemplar first embodiment;

FIG. 4 is a front view showing the casing of the air-bag control device according to the exemplar embodiment;

FIG. 5 is a side view showing the casing of the air-bag control device according to the exemplar embodiment;

FIG. 6 is a top view showing a cover of the air-bag control device according to the exemplar embodiment;

FIG. 7 is a front view showing the cover of the air-bag control device according to the exemplar embodiment;

FIG. 8 is a side view showing the cover of the air-bag control device according to the exemplar embodiment;

FIG. 9 is a top view showing the air-bag control device according to the exemplar embodiment;

FIG. 10 is a front view showing the air-bag control device according to the exemplar embodiment;

FIG. 11 is a side view showing the air-bag control device according to the exemplar embodiment;

FIG. 12 is a schematic diagram showing a part of the air-bag control device including an eaves portion of FIG. 11;

FIG. 13 is a side view showing a casing according to a modification of the present disclosure;

FIG. 14 is a side view showing a casing according to another modification of the present disclosure; and

FIG. 15 is a front view showing a casing according to another modification of the present disclosure.

### DETAILED DESCRIPTION

An exemplar embodiment will be described in reference to drawings. In the exemplar embodiment, an electronic device of the present disclosure is applied to an air-bag control device provided in a vehicle.

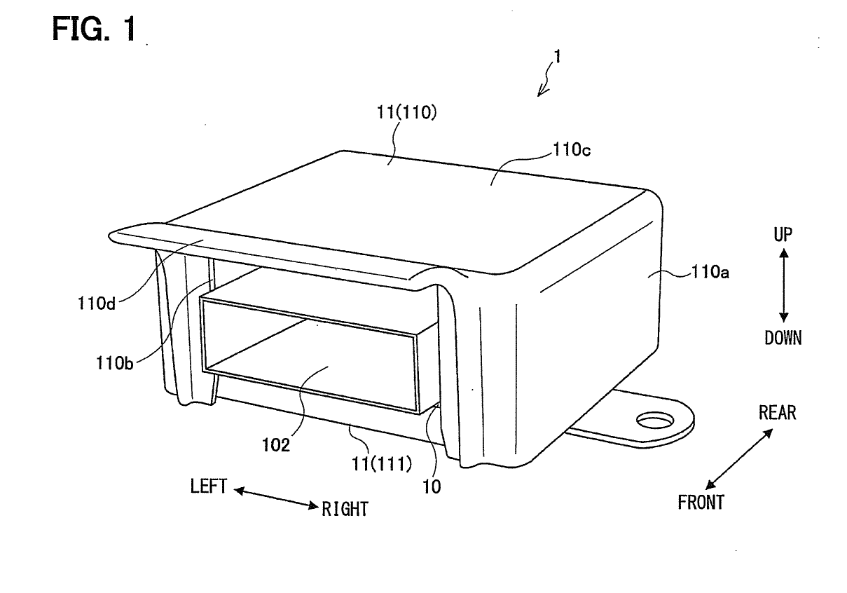

An air-bag control device 1 of the exemplar embodiment will be described referring to FIGS. 1 to 11. Up-down arrows in the drawings indicate an up-down direction of the air-bag control device 1 when the air-bag control device 1 is disposed in a vehicle. In other words, the up-down arrows indicate an up-down direction of the vehicle. On the other hand, front-rear arrows and right-left arrows do not indicate directions of the air-bag control device when the air-bag control device is disposed in the vehicle. The front-rear arrows and right-left arrows are illustrated just for differentiating directions. In the drawings, a pin of a connector 102 is omitted.

The air-bag control device 1 shown in FIG. 1 is disposed in a vehicle and is used for controlling deployment of an air-bag based on detection results from an acceleration sensor provided inside the air-bag control device 1 and from acceleration sensors provided in various parts of the vehicle. The air-bag control device 1 includes a substrate 10, a housing 11, and bolts 12 and 13.

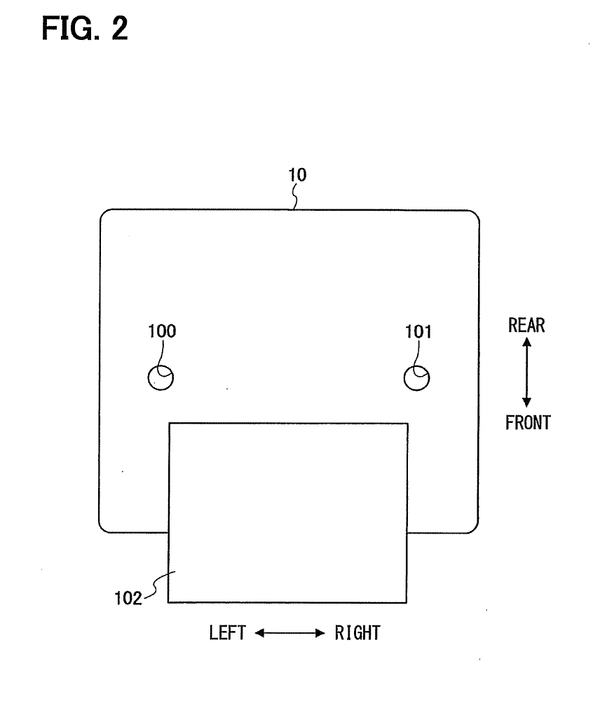

The substrate 10 made of resin has a rectangular shape. The substrate 10 is provided with electronic parts and fixes the electronic parts for providing an electronic circuit. As shown in FIG. 2, the substrate 10 has through holes 100 and 101. Additionally, the substrate 10 is provided with the connector 102.

The thorough holes 100 and 101 are circle holes through which the bolts 12 and 13 extend to fix the substrate 10 to the housing 11 in the up-down direction. The through holes 100 and 101 are provided in an approximately middle part of the substrate 10 in the front-rear direction and are distant from each other in the right-left direction.

The connector 102 is used for connecting the air-bag control device 1 to the air-bag and the acceleration sensors provided in various parts of the vehicle. The connector 102 is provided on and fixed to a front rim portion of an upper surface of the substrate 10, and an end portion of the connector 102 protrudes from the front rim portion of the substrate 10 frontward.

As shown in FIG. 1, the housing 11 having a hollow cuboid shape accommodates and fixes the substrate 10 therein while the connector 102 protrudes frontward to be exposed to an exterior of the housing 11. The housing 11 includes a casing 110 (electronic device casing) and a cover 111.

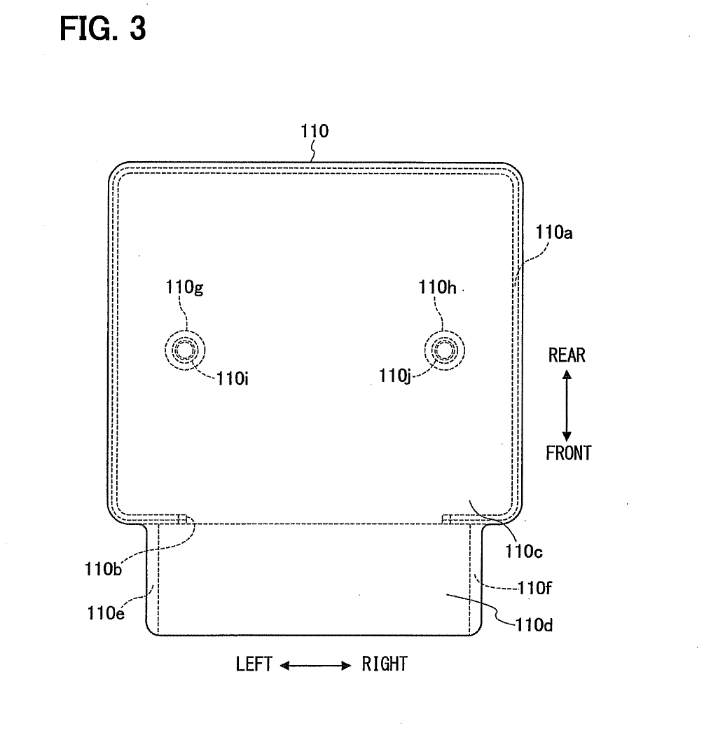

The casing 110 accommodates and fixes the substrate 10 therein while the connector 102 protrudes from the front rim portion of the substrate 10 frontward to be exposed to the exterior of the casing 110. The casing 110 made of resin has a rectangular box shape and has an opening on its bottom part. As shown in FIGS. 3 to 5, the casing 110 includes a peripheral wall portion 110a, an opening portion 110b, an upper plate portion 110c, an eaves portion 110d, side wall portions 110e and 110f, protruding portions 110g and 110h, and nuts 110i and 110j.

The peripheral wall portion 110a has a rectangular cylindrical shape and encloses an outer circumference of the substrate 10 provided with the connector 102.

The opening portion 110b is formed in the peripheral wall portion 110a and has a rectangular opening from which the connector 102 is exposed to the exterior of the casing 110. In other words, the end portion of the connector 102 protrudes from the opening portion 110b frontward. The opening portion 110b is formed on a front side of the peripheral wall portion 110a as shown in FIGS. 3 to 5.

The upper plate portion 110c has a rectangular plate shape and covers an upper part of the peripheral wall portion 110a.

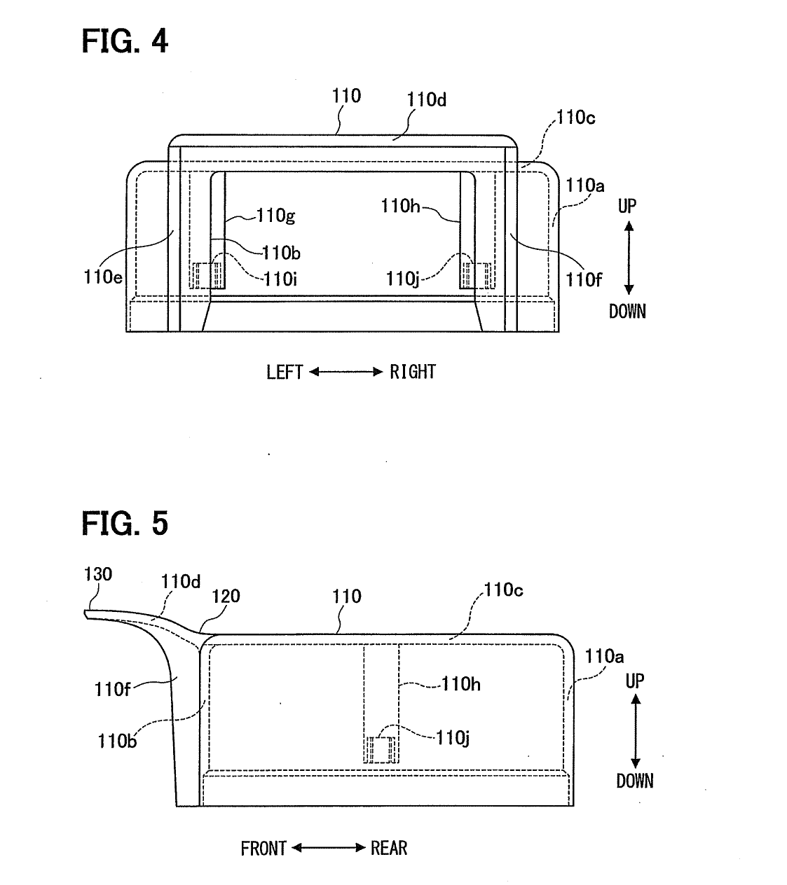

The eaves portion 110d has a curved rectangular shape and protrudes frontward from a front end part of the upper plate portion 110c as shown in FIG. 5. The eaves portion 110d covers an upper part of the connector 102 exposed from the opening portion 110b, thereby limiting exposure of the connector 102 to water. As shown in FIG. 5, the eaves portion 110d has a first end part 120 connected to the upper plate portion 110c, and a second end part 130 opposite from the first end part 120 in the protruding direction of the eaves portion 110d. The second end part 130 is higher than the first end part 120 of the eaves portion 110d. For example, the height of the eaves portion 110d increases gradually from the first end part 120 to the second end part 130. More specifically, the height of the eaves portion 110d increases gradually from the first end part 120 to the second end part 130 such that the eaves portion 110d has an elliptically-curved shape. In other words, the eaves portion 110d curves elliptically from the first end part 120 to the second and part 130. As shown in FIGS. 4 and 5, the eaves portion 110d has the same height in the right-left direction (horizontal direction) with respect to each position of the eaves portion 110d in the front-rear direction. Hence, the second end part 130 of the eaves portion 110d extends horizontally in the right-left direction as shown in FIG. 4. The eaves portion 110d may be used as an example of a protrusion portion that protrudes from the end part of the upper plate portion 110c and covers the upper part of the connector 102 exposed from the opening portion 110b.

The side wall portion 110e has a plate-like shape and protrudes from an outer circumferential surface of the peripheral wall portion 110a frontward. The side wall portion 110e covers a left side part of the connector 102 exposed from the opening portion 110b, thereby limiting exposure of the connector 102 to water. An upper and part of the side wall portion 110e is connected to a left end part of the eaves portion 110d.

The side wall portion 110f has a plate-like shape and protrudes from an outer circumferential surface of the peripheral wall portion 110a frontward. The side wall portion 110f covers a right side part of the connector 102 exposed from the opening portion 110b, thereby limiting exposure of the connector 102 to water. An upper end part of the side wall portion 110f is connected to a right end part of the eaves portion 110d.

The protruding portions 110g and 110h have circular cylindrical shapes and protrude downward from a lower surface of the upper plate portion 110c. As shown in FIG. 3, the protruding portions 110g and 110h are provided an approximately middle part of the upper prate portion 110c in the front-rear direction. The protruding portions 110g and 110h are distant from each other in the right-left direction.

The nuts 110i and 110j shown in FIGS. 3 and 4 fix the substrate 10 to the housing 11 by being threadedly engaged with the bolts 12 and 13. As shown in FIG. 4, the nuts 110i and 110j are provided in end parts of the protruding portions 110g and 110h, respectively. Therefore, as shown in FIG. 3, the nuts 110i and 110j are provided at an approximately middle part of the upper plate portion 110c in the front-rear direction, and are distant from each other in the right-left direction.

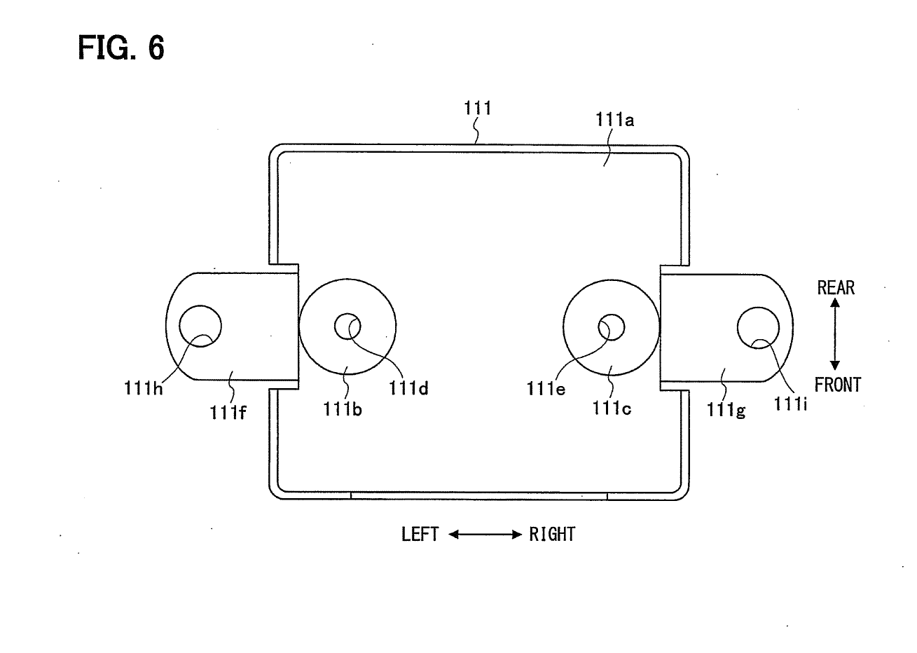

As shown in FIG. 1, the cover 111 made of metal has a plate-like shape and covers a lower part of the peripheral wall portion 110a. As shown in FIGS. 6 to 8, the cover 111 includes a bottom plate portion 111a, protruding portions 111b and 111c, through holes 111d and 111e, protruding portions 111f and 111g, and through holes 111h and 111i.

The bottom plate portion 111a has a rectangular shape and covers the lower part of the peripheral wall portion 110a.

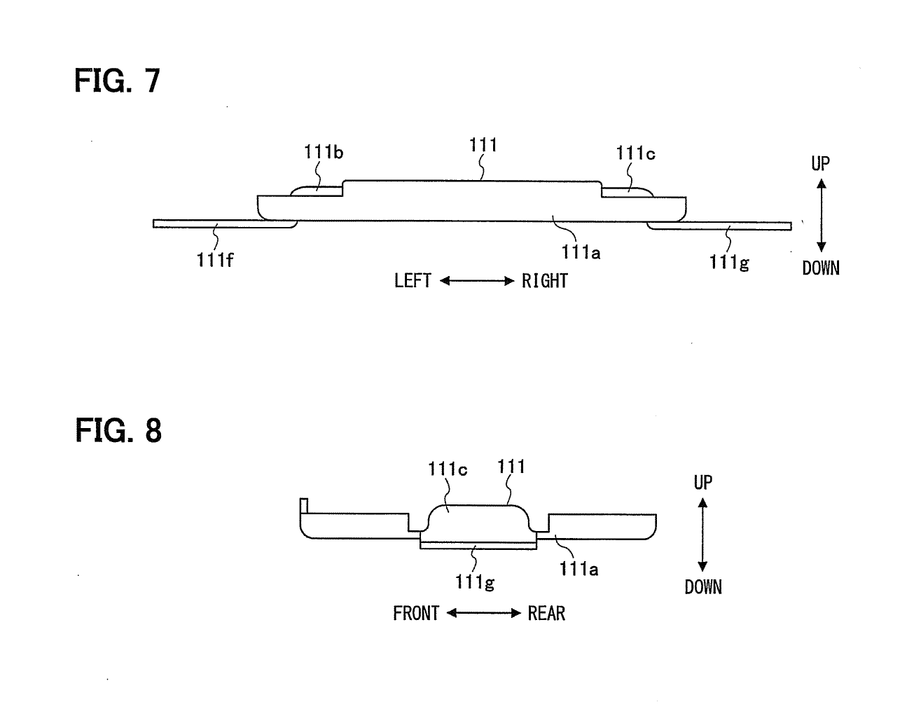

As shown in FIGS. 6 and 7, the protruding portion 111b has a circular cylindrical shape and is located at an approximately middle part of the bottom plate portion 111a in the front-rear direction. The protruding portion 111b protrudes upward from a left rim part of the bottom plate portion 111a and supports the substrate 10.

The protruding portion 111c has a circular cylindrical shape and is located at an approximately middle part of the bottom plate portion 111a in the front-rear direction. The protruding portion 111c protrudes upward from a right rim part of the bottom plate portion 111a and supports the substrate 10.

As shown in FIG. 6, the through holes 111d and 111e are circular holes through which the bolts 12 and 13 are inserted. The through holes 111d and 111e are provided in the protruding portions 111b and 111c, respectively. The through holes 111d and 111e are located at an approximately middle part of the bottom plate portion 111a in the front-rear direction. The through holes 111d and 111e are distant from each other in the right-left direction.

As shown in FIGS. 6 and 7, the protruding portion 111f having a plate-like shape is located at an approximately middle part of the bottom plate portion 111a in the front-rear direction. The protruding portion 111f protrudes leftward from a left rim part of the bottom plate portion 111a.

The protruding portion 111g having a plate-like shape is located at an approximately middle part of the bottom plate portion 111a in the front-rear direction. The protruding portion 111g protrudes rightward from a right rim part of the bottom plate portion 111a.

As shown in FIG. 6, the through holes 111h and 111i are circular holes through which bolts are inserted so as to fix the cover 111 to the vehicle in the up-down direction. The through hole 111h is provided in the protruding portion 111f to be distant from the through hole 111d. Thus, the through hole 111h is located on an outer side of the through hole 111d in the right-left direction, in other words, the through hole 111h is located on a left side of the through hole 111d. The through hole 111i is provided in the protruding portion 111g to be distant from the through hole 111e. Thus, the through hole 111i is located on an outer side of the through hole 111e in the right-left direction, in other words, the through hole 111i is located on a right side of the through hole 111e.

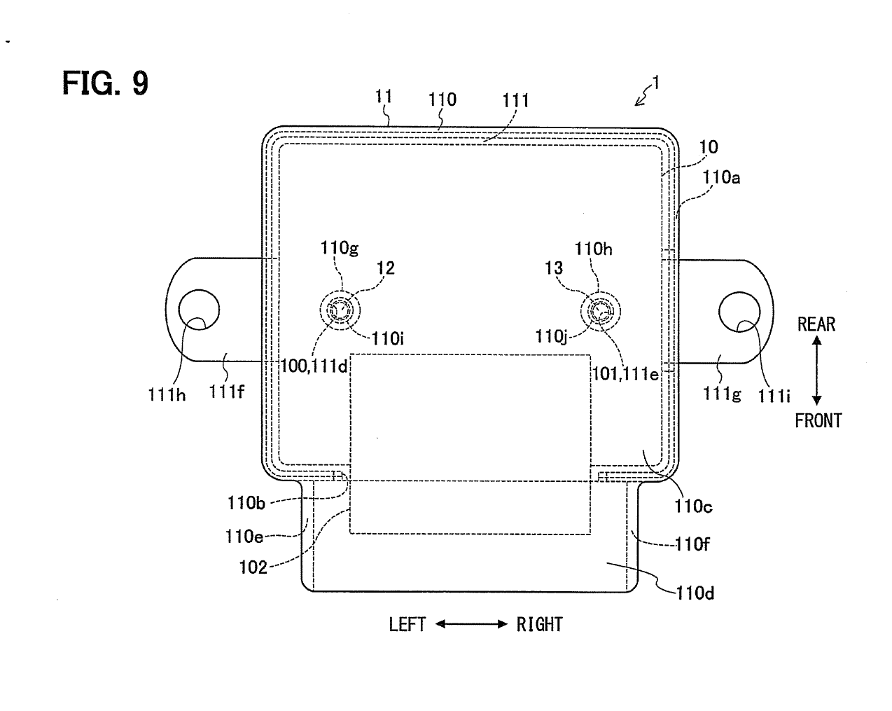

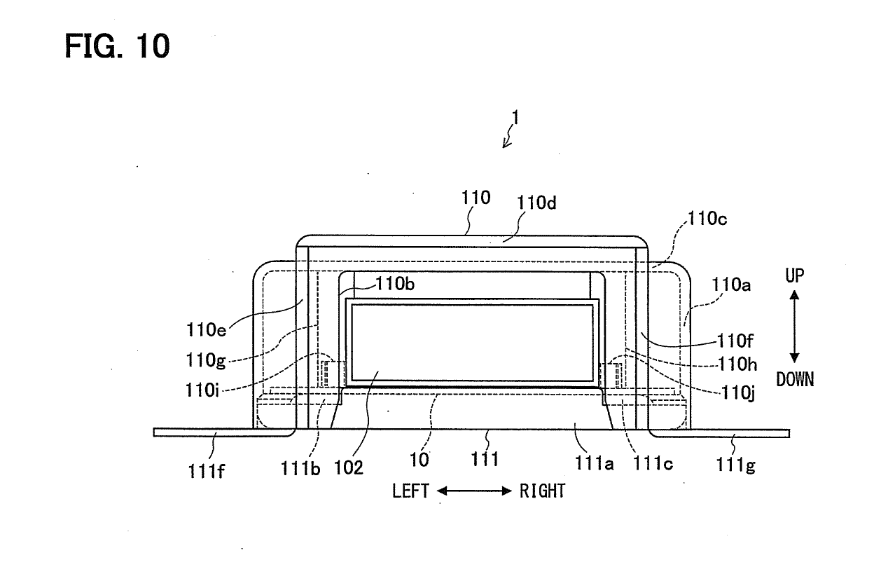

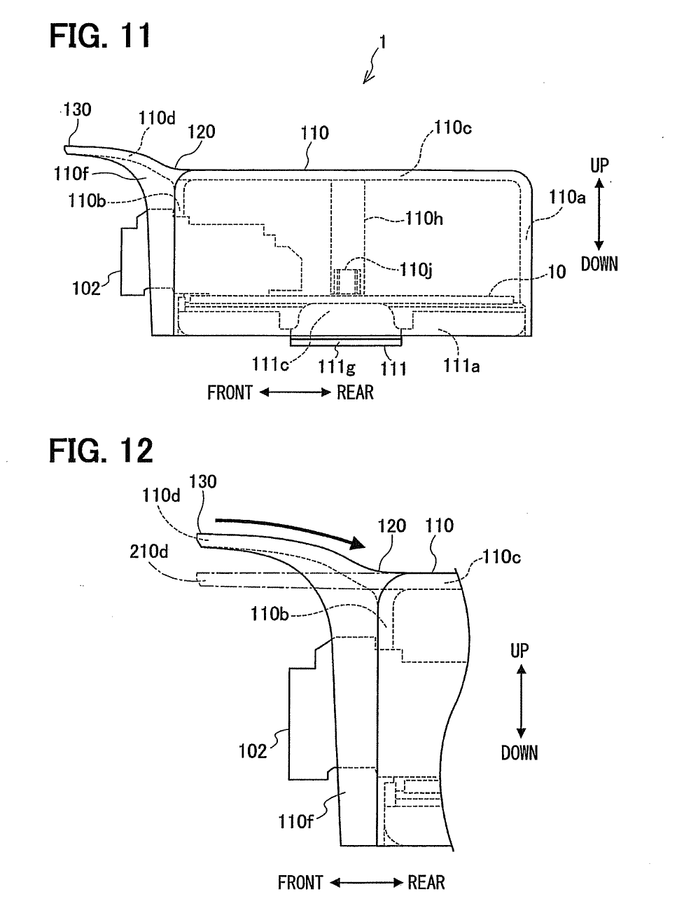

The bolts 12 and 13 shown in FIGS. 9 to 11 fix the substrate 10 to the housing 11. As shown in FIGS. 9 and 10, the bolts 12 and 13 are inserted into the nuts 110i and 110j of the casing 110 from underneath the cover 111 via the through holes 111d and 111e of the cover 111 and the through holes 100 and 101 of the substrate 10. The bolts 12 and 13 are screwed with the nuts 110i and 110j to fix the substrate 10 to the housing 11 in the up-down direction. Specifically, as shown in FIGS. 10 and 11, the substrate 10 is fixed to the housing 11 while the substrate 10 is sandwiched between the protruding portion 111b of the cover 111 and the protruding portion 110g of the casing 110 and between the protruding portion 111c of the cover 111 and the protruding portion 110h of the casing 110.

Effects of the present disclosure will be described with reference to FIGS. 3 to 5 and 12.

According to the exemplar embodiment, as shown in FIG. 12, the second end part 130 of the eaves portion 110d is higher than the first end part 120 of the eaves portion 110d. Thus, a space between the connector 102 and the eaves portion 110d can be made to be wider as compared with a case in which an eaves portion 210d protrudes frontward horizontally from the front end part of the upper plate portion 110c. Hence, it can be limited that a finger of a worker contacts the eaves portion 110d when another connector is inserted into or pulled out of the connector 102. Accordingly, resistance of the connector 102 to water can be ensured by the eaves portion 110d, and workability of the connection or disconnection of the connector 102 can be improved.

According to the exemplar embodiment, as shown in FIG. 12, the height of the eaves portion 110d increases gradually from the first end part 120 to the second end part 130 of the eaves portion 110d. In other words, an upper surface of the eaves portion 110d gradually lowers from the second end part 130 to the first end part 120. Even when water is poured over the eaves portion 110d, the water can be guided toward the upper plate portion 110c promptly as shown by the bold arrow in FIG. 12. Therefore, exposure of the connector 102 to water can be limited certainly.

According to the exemplar embodiment, as shown in FIG. 5, the eaves portion 110d has height that increases gradually from the first end part 120 to the second end part 130 of the eaves portion 110d such that the eaves portion 110d has an elliptically-curved shape. The eaves portion 110d curves elliptically between the first end part 120 and the second end part 130 of the eaves portion 110d. Thus, the height of the eaves portion 110d can be certainly made to increase gradually from the first end part 120 to the second end part 130. In other words, the upper surface of the eaves portion 110d can be certainly made to gradually lower from the second end part 130 to the first end part 120.

According to the exemplar embodiment, as shown in FIGS. 4 and 5, the eaves portion 110d has the same height in the right-left direction with respect to each position of the eaves portion 110d in the front-rear direction. The second end part 130 of the eaves portion 110d extends horizontally in the right-left direction. Even when water is poured over the eaves portion 110d, the water is not guided rightward or leftward. Therefore, exposure of the connector 102 to water from the right and left sides of the connector 102 can be limited.

According to the exemplar embodiment, as shown in FIGS. 3 and 4, the casing 110 includes the side wall portions 110e and 110f which have plate-like shapes and protrude frontward from the outer circumferential surface of the peripheral wall portion 110a to cover the right side portion and the left side portion of the connector 102 exposed from the opening portion 110b. Therefore, exposure of the connector 102 to water from the right and left sides of the connector 102 can be limited certainly.

Although the present disclosure has been fully described in connection with the preferred embodiments thereof with reference to the accompanying drawings, it is to be noted that various changes and modifications described below will become apparent to those skilled in the art.

In the exemplar embodiment, the height of the eaves portion 110d increased gradually from the first end part 120 to the second end part 130 such that the eaves portion 110d has the elliptically-curved shape. However, the shape of the eaves portion 110d is not limited to this.

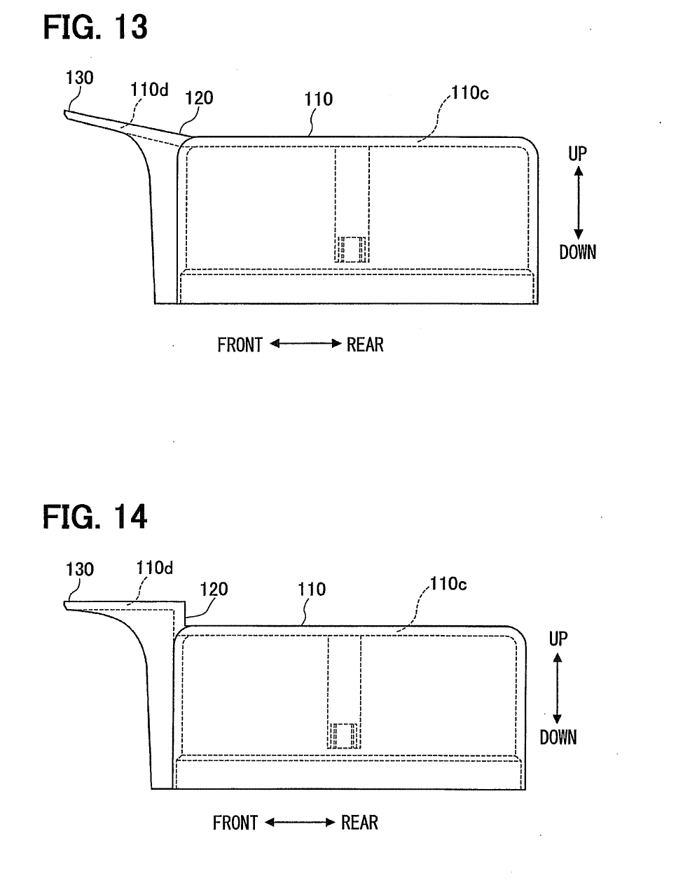

As shown in FIG. 13, the height of the eaves portion 110d may increase gradually and linearly from the first end part 120 to the second end part 130. In this case, the space between the eaves portion 110d and the connector 102 mounted on the substrate 10 becomes narrow measurably, but effects similar to those of the exemplar embodiment can be obtained.

Alternatively, as shown in FIG. 14, the eaves portion 110d may extend upward from the first end part 120 and may protrude frontward horizontally. In this case, the height of the eaves portion 110d does not increase gradually from the first end part 120 to the second end part 130. Thus, water poured over the eaves portion 110d cannot be guided toward the upper plate portion 110c promptly, but water poured over the upper plate portion 110c can be prevented from flowing toward the eaves portion 110d. Hence, inflow of water through a clearance of the connector 102 or a clearance of the housing 11 can be limited. Additionally, effects similar to those of the exemplar embodiment can be obtained. Since a space between the eaves portion 110d and the connector 102 mounted on the substrate 10 can be more widen, the workability of connection or disconnection of the connector 102 can be improved.

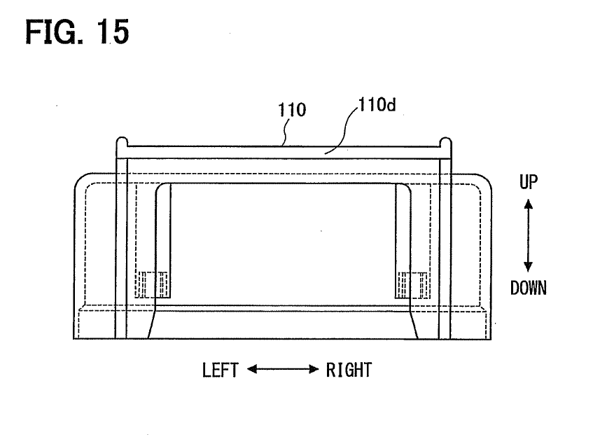

In the exemplar embodiment, the eaves portion 110d has the same height in the right-left direction with respect to each position of the eaves portion 110d in the front-rear direction. However, the height of the eaves portion 110d in the right-left direction is not limited to this. As shown in FIG. 15, heights of both end parts of the eaves portion 110d in the right-left direction may be higher than the other parts of the eaves portion 110d with respect to each position of the eaves portion 110d in the front-rear direction. In this case, exposure of the connector 102 to water from the right and left sides of the connector 102 can be restricted certainly.

In the exemplar embodiment, the electronic device casing of the present disclosure is applied to the air-bag control device, but the application of the electronic device casing is not limited to this. The electronic device casing of the present disclosure can be applied to any casing accommodating a substrate provided with a connector.

Additional advantages and modifications will readily occur to those skilled in the art. The disclosure in its broader terms is therefore not limited to the specific details, representative apparatus, and illustrative examples shown and described.

What is claimed is:

1. An electronic device casing comprising:
a peripheral wall portion enclosing an outer circumference of a substrate provided with a connector;
an opening portion formed in the peripheral wall portion to have an opening from which the connector is exposed to an exterior of the peripheral wall portion;
an upper plate portion covering an upper part of the peripheral wall portion; and
a protrusion portion protruding from an end part of the upper plate portion and covering an upper part of the connector exposed from the opening portion, wherein
the protrusion portion has a first end part connected to the upper plate portion, and a second end part opposite from the first end part in a protruding direction of the protrusion portion, and
the second end part is higher than the first end part.

2. The electronic device casing according to claim 1, wherein the protrusion portion has height that increases gradually from the first end part to the second end part.

3. The electronic device casing according to claim 2, wherein the protrusion portion curves elliptically from the first end part to the second end part.

4. The electronic device casing according to claim 1, wherein the protrusion portion has the same height in a direction perpendicular to the protruding direction of the protrusion portion with respect to each position of the protrusion portion in the protruding direction.

5. The electronic device casing according to claim 1, wherein both end parts of the protrusion portion in a direction perpendicular to the protruding direction of the protrusion portion are higher than the other parts of the protrusion portion with respect to each position of the protrusion portion in the protruding direction.

6. The electronic device casing according to claim 1, further comprising side wall portions protruding from an outer circumferential surface of the peripheral wall portion and covering both side portions of the connector exposed from the opening portion.
